(19) United States
(12) Patent Application Publication
(10) Pub. No.: US 2004/0175902 A1
(43) Pub. Date: Sep. 9, 2004

(54) Method of obtaining a self-supported thin semiconductor layer for electronic circuits

(76) Inventors: Olivier Rayssac, Grenoble (FR); Carlos Mazure, St. Nazaire les Eymes (FR); Bruno Ghyselen, Seyssinet-Pariset (FR)

Correspondence Address: WINSTON & STRAWN, PATENT DEPARTMENT, 1400 L STREET, N.W., WASHINGTON, DC, 20005-3502, US

(21) Appl. No.: 10/775,917

(22) Filed: Feb. 9, 2004

Related U.S. Application Data
(63) Continuation of application No. PCT/FR02/02879, filed on Aug. 14, 2002.

(30) Foreign Application Priority Data
Aug. 14, 2001 (FR) 0110813

(51) Int. Cl. H01L 21/30; H01L 21/46

(52) U.S. Cl. 438/459; 438/458

(57) ABSTRACT

The invention relates to a method of producing a self-supported thin layer of a semiconductor material supporting at least one electronic component or circuit or both on one of its faces, from a wafer of the material by thinning of the wafer. The wafer has a front face supporting or for supporting at least one electronic component or circuit and a rear face. The method is remarkable in that it includes: a) implanting atomic species in the interior of the wafer through its rear face to obtain a zone of weakness defining a front portion extending from the front face of the zone of weakness and a rear portion formed by the remainder of the wafer; b) detaching the rear portion from the front portion; and c) if necessary, repeating steps a) and b) on the rear face of the front portion until the front portion has the desired thickness for constituting the self-supported thin layer.

### CROSS-REFERENCE TO RELATED APPLICATION

This application is a continuation of International application PCT/FR02/02879 filed Aug. 14, 2002, the entire content of which is expressly incorporated herein by reference thereto.

### BACKGROUND ART

The present invention relates to a method of obtaining a self-supported thin layer of a semiconductor material, supporting or for supporting at least one electronic component and/or circuit.

In certain fields of electronics, optics, optoelectronics, or sensors, technical advances have pushed manufacturers towards the fabrication of thinner and thinner layers provided with electronic components and circuits.

In the particular field of smart cards, there is a need for them to become thinner and thinner and thus flexible, since they will then be more tolerant to deformation. In other words, at constant deformation, the more flexible the thin layer, the greater the possibility of producing circuits of large dimensions.

In certain radio frequency type applications, an integrated circuit carried on the front face of a wafer constituted by a silicon on insulator (SOI) type substrate is coupled to an antenna to produce contact-free detection. An example is a bus or metro ticket that can validate passage for one person remote from a transceiver station.

By coupling the advantages provided by components produced on a silicon on insulator substrate, using the thinnest possible active layers, it is possible to obtain a product—for example a ticket—with enhanced sensitivity and for which the mechanical resistance to external stresses is very greatly improved.

Currently, the thickness of thin films before embedding (i.e. fixing the chip on the plastics card acting as the support) is of the order of one hundred micrometers.

The technique used to obtain this range of thickness includes carrying out a thinning operation on the rear face of a substrate, i.e. the face opposite to that supporting the electronic components. That thinning is carried out by mechanical abrasion using a grinder (grinding) and/or by chemical attack using an acid (one technique is known as spin-etching). Thin layers are thus obtained with a thickness in the range 80 micrometers (μm) to 120 μm. That technique allows high volume production.

A variety of attempts have already been made to obtain thin layers with a final thickness of less than 100 μm. However, manufacturers have come up against problems regarding yield, because of the large number of defective parts obtained, especially due to notches or cleavage of the wafers. The smart card field is one of the fields in electronics in which costs have to be as low as possible and because of this fact, yield losses of a few percent or even a few tenths of a percent cannot be tolerated.

However, because of the predicted future development of smart cards, it would be desirable to produce self-supported thin layers or thin wafers with a thickness of close to 30 μm, and supporting electronic components and/or circuits.

The prior art discloses known methods of producing self-supported layers with thickness close to a few tens of micrometers.

U.S. Pat. No. 6,100,166 describes a method of fabricating a semiconductive article in which the surface of a monocrystalline silicon substrate is rendered porous, then a layer of non-porous silicon with the desired thickness of the active layer is grown epitaxially on that porous layer. A porous, and thus weakened, layer is thus obtained, buried between two non-porous silicon layers. The active surface silicon layer can then be treated to deposit additional layers thereon, for example doped layers, then an adhesive film is applied to that stack of layers. Finally, after peeling off the adhesive film and breaking the stack of layers at the porous layer, and then subsequent elimination of the residue of that porous layer, it becomes possible to produce electronic components on the active layer of silicon which can be self-supported.

Unfortunately, that method comes up against problems connected with the quality of the crystalline silicon layer formed on the porous layer and with producing the porous silicon layer. Production requires unusual equipment and introduces the possibility of metal contamination.

Further, that method necessitates the fabrication of a specific substrate prior to producing the electronic components, which means that component production method has to be significantly modified. Thus, it is not generally desirable for reasons of cost.

Techniques for obtaining thin layers are also known, based on the method known under the trade name “Smart-cut”, which is well known to the skilled person.

All techniques for obtaining thin layers involve implanting atomic species in the front face of the substrate or wafer, i.e. the face carrying or intended to carry electronic components.

U.S. Pat. No. 6,103,597 discloses a method of implanting ions that generate gas micro-bubbles on the front face of the substrate after fabricating the electronic components.

However, implanting ions through electrically active layers constituting electronic components can create defects which render such components unusable.

U.S. Pat. No. 6,316,333 claims to overcome that problem by masking sensitive active zones and then producing a discontinuous zone of weakness. However, that method remains difficult to carry out.

Finally, U.S. Pat. No. 6,020,252 offers another solution to the problem mentioned above of electronic component. dysfunction. The method disclosed therein includes carrying out ion implantation on the front face of a substrate prior to fabricating electronic components on the same face, then only subsequently carrying out separation of the thin layer.

However, that method requires the production of a specific substrate prior to producing the electronic components, which may mean that the component fabrication method has to be significantly modified. This is not generally desirable for reasons of cost. Thus, improvements in these methods are desired.

### SUMMARY OF THE INVENTION

The present invention overcomes the problems mentioned above and provides a self-supported layer carrying electronic components and/or circuits, i.e., a layer that is less than 30 μm thick.

To this end, the invention relates to a method of thinning a wafer made of semiconductor material, the wafer having a first face supporting or for supporting at least one electronic component or circuit and an opposing second face. This method comprises implanting atomic species through the second face and into the wafer to obtain a zone of weakness at a predetermined depth therein, with the zone defining a first portion of the wafer extending from the zone to the first face and a remaining portion constituted by the remaining portion of the wafer. Next, the remaining portion is removed from the first portion along the zone of weakness to thin the wafer. Thereafter, the implanting and removing steps are repeated until the first portion has a reduced thickness that corresponds to a desired thickness for constituting a self-supported thin layer for the electronic component or circuit.

If desired, the method can further include thinning the wafer by a mechanical or chemical thinning method prior to the implanting of the atomic species. Preferably, at least one electronic component or circuit can be produced on the first face of the wafer prior to the implanting of the atomic species.

### BRIEF DESCRIPTION OF THE DRAWING FIGURES

Other characteristics and advantages of the invention become apparent from the following description of three preferred implementations of the invention, given by way of non-limiting illustrative examples. This description is made with reference to the accompanying drawings in which:

FIGS. 1 to 6 are diagrams illustrating the different successive steps of a first implementation of the method of the invention;

FIGS. 7 to 12 are diagrams illustrating the different successive steps of a second implementation of the method of the invention;

FIGS. 13 to 17 are diagrams illustrating the successive steps of a third implementation of the method of the invention; and

FIGS. 18 to 21 are diagrams illustrating the successive steps of a variation of the method.

### DETAILED DESCRIPTION OF THE PREFERRED EMBODIMENTS

In this invention, the wafer has a first face termed the “front face” supporting—or for supporting—at least one electronic component or circuit and an opposing face, termed the “rear face”.

According to a preferred embodiment of the invention, this method comprises the steps of:

a) implanting atomic species in the interior of the wafer from its rear face, to obtain a zone of weakness and a rear portion formed by the remainder of the wafer;

b) detaching the rear portion from the front portion, to thin the wafer; and

c) if necessary, repeating steps a) and b) on the rear face of the front portion until the front portion has the desired thickness for constituting the self-supported thin layer.

The characteristics of the invention render it possible to obtain thin layers in high yields that are difficult to obtain with prior art techniques, without having to modify the electronic component fabrication method or producing a specific wafer, as was often the case in the prior art.

Other advantageous but non-limiting characteristics of the invention, taken alone or in combination, are now mentioned.

Prior to any first implantation step a), the method can includes thinning of the wafer by a mechanical and/or chemical thinning method which is carried out on the rear face. This assists in thinning the wafer and shortening the processing time to obtain the self-supported thin layer.

Also, at least one electronic component, circuit or both can be applied on the front face of the wafer prior to an implantation step. When multiple implantation steps are conducted, this can be done before any one of them.

The step of detaching the rear portion can be carried out by applying a heat treatment and/or applying external mechanical stresses, by blowing a jet of fluid or by scrubbing. The step of detaching the rear portion also can be carried out by applying a stiffener to the rear face of the wafer, then applying a heat treatment and/or external mechanical stresses to the stiffener. These techniques are generally known to skilled artisans.

The stiffener can be applied by deposition and can be a layer of silicon oxide or a rigid plate formed from monocrystalline or polycrystalline silicon, or from glass. Alternatively, the stiffener can be a flexible film, an adhesive film, or a layer of wax, as desired. Prior to the step of detaching the rear portion, the stiffener can be applied to the front face of the wafer and then removed after having obtained the self-supported thin layer.

The wafer can be formed from silicon, or can be a silicon on insulator wafer. Also, the wafer can be produced from germanium, an alloy of silicon and germanium (Si—Ge), silicon carbide, gallium arsenide, indium phosphide (InP), gallium nitride (GaN) or aluminum nitride (AlN).

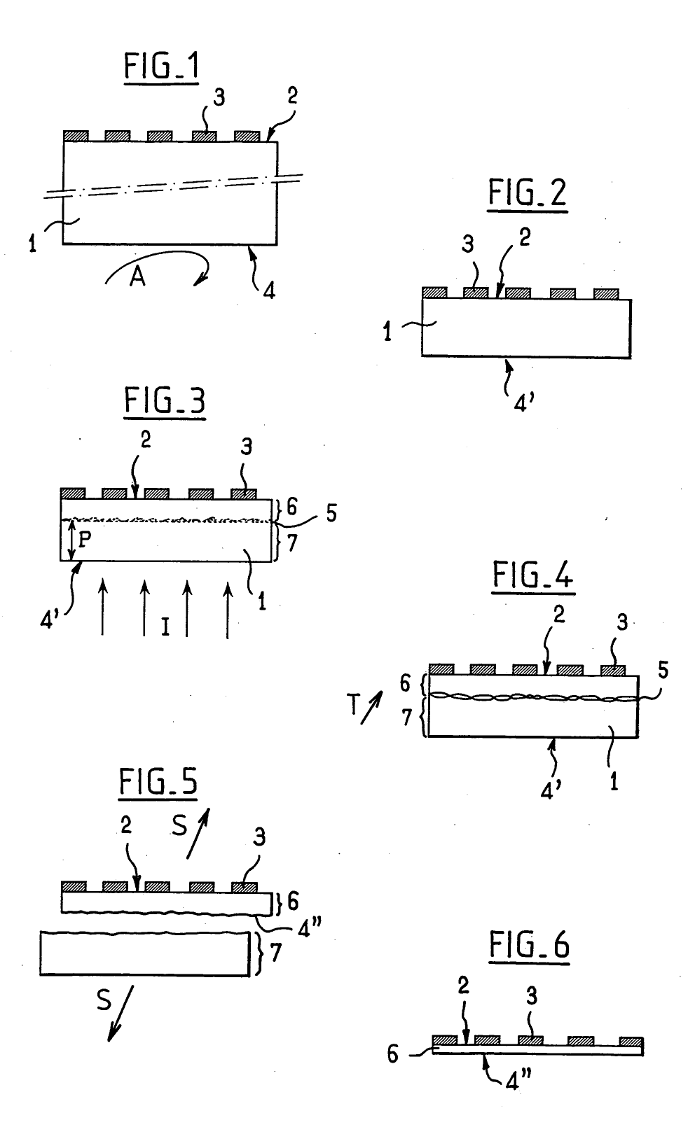

It should be noted that in the three implementations of the method of the invention described, the first two steps (illustrated respectively in FIGS. 1 and 2 for the first implementation, 7 and 8 for the second implementation and 13 and 14 for the third implementation) are identical. As a result, they are described in detail only for the first implementation.

FIG. 1 shows a wafer 1 having a first planar face termed the “front face” supporting—or for supporting—at least one electronic component and/or circuit 3, and a second opposing planar face 4, termed the “rear face”.

The term “electronic component and/or circuit” means any completely or partially produced structure or structural element prepared with the aim of producing components, circuits and devices in the electronics, optics, optoelectronics, or sensor fields, and more generally in the fields of applications connected with semiconductors.

The expression “supporting—or for supporting—at least one electronic component or circuit” means that the component(s) or circuit(s) or both have either already been produced on the front face 2 of the wafer 1 prior to commencing the steps of the method of the invention, or will subsequently be produced, but on the front face 2, while all of the other steps of the method of the invention will be carried out on the opposing face termed the “rear face”.

For simplification, in the remainder of the description (and as shown in the figures), we have elected to describe the case in which the components and/or circuits 3 have been produced on the wafer 1 prior to carrying out the various thinning steps of the method of the invention.

It should be noted that in prior art methods in which the components 3 are produced after thinning, they have been produced on the front face 2.

The wafer 1 is produced from a semiconductor material, which can be monocrystalline, polycrystalline or amorphous, in particular from a silicon-based material.

The silicon can be-solid, or it can be obtained by epitaxial growth on a substrate.

The wafer 1 can also be a “silicon on insulator” wafer, i.e., comprising a thin layer of insulator (for example silicon oxide) inserted between an active silicon layer on which the electronic circuit is etched and a substrate acting as a mechanical support. Such a wafer is known by the acronym “SOI”.

In a variation, the wafer 1 can also be produced from a material selected from germanium, an alloy of silicon and germanium (Si—Ge), silicon carbide, gallium arsenide, indium phosphide (InP), gallium nitride (GaN) or aluminum nitride (AlN).

The wafer 1 is a few hundred micrometers thick (as an example, a 200 millimeter (mm) diameter silicon wafer is about 725 μm thick). Thus, the wafer 1 is not shown to scale in FIG. 1.

The rear face 4 of the wafer 1 is then thinned employing one of the conventional methods mentioned above, i.e. mechanical abrasion and/or chemical acid attack, as shown symbolically by arrow A. It would also be possible to thin down by plasma etching. The rear face 4 is the face which does not carry electronic components.

The thinned wafer illustrated in FIG. 2 is obtained with thickness in the range 80 μm to 120 μm, or even 50 μm.

The rear face of the thinned wafer carries reference numeral 4′.

This step is advantageous in that it can remove a large quantity of material cheaply using a technique that is well known to the skilled person and in routine use. However, it can only be continued until a thin layer of the desired thickness is obtained since, as explained above, it results in large reduction in yield.

Continuing this method beyond thicknesses of 50 μm mentioned above greatly increases the risk of wafer rupture or notching.

Furthermore, the thickness obtained, in particular after chemical etching, is no longer homogeneous.

Further still, mechanical thinning by grinding leaves a surface zone a few microns thick that is slightly damaged—which is unacceptable when approaching the final thickness.

Finally, after chemical attack, the wafer is generally attacked more strongly at its periphery than at its center. When small thicknesses are reached, this results in a reduction in diameter and thus in a reduction in the area that can be occupied by components.

However, it should be noted that this first mechanical and/or chemical thinning step, albeit advantageous from an economical viewpoint, is optional and the subsequent step of implanting atomic species could be carried out directly on the rear face 4 of the non-thinned wafer 1.

The third step of the method shown in FIG. 3 includes implanting atomic species (arrows I) in the interior of the wafer 1, to obtain a zone of weakness 5 or a zone for the appearance of defects, at a depth close to the mean implantation depth P for the atomic species.

In accordance with a fundamental characteristic of the invention, the implantation is carried out from the rear face 4′ (or 4 if the wafer has not been thinned in advance).

The term “atomic species implantation” means any bombardment of atomic species, molecular or ion, capable of introducing the species into a material with a maximum concentration of the species in the material, that maximum being located at a depth that is determined with respect to the bombarded surface. The molecular or ion atomic species are introduced into the material with energy that is also distributed about a maximum.

Implanting atomic species into the material can be carried out, for example, using an ion beam implanter or a plasma immersion implanter.

Preferably, the implantation is accomplished by ion bombardment. This includes an ion implantation step during which the rear race of the wafer 1 is bombarded with atomic species. Preferably, these are selected from rare gas ions (helium, neon, krypton, xenon) and hydrogen gas, taken in isolation or in combination, to create a zone of weakness 5 in the volume of the substrate at a mean ion penetration depth. However, the implanted atomic species is most preferably hydrogen.

The zone of weakness 5 that is formed defines a front portion 6 corresponding to the upper portion of the wafer 1 extending from the front face 2 supporting components 3 to the zone of weakness 5 and a rear portion 7 formed by the remainder of the wafer 1.

The energy of the implanted atomic species determines the mean species implantation depth P, calculated from the surface of the rear face 4′, while the mean implanted dose allows the quantity of structural defects formed at that depth P to be determined. The skilled person will adjust these two parameters as a consequence. The expression “mean depth P” means that it does not have a single value, but can have several similar values.

In the implementation shown in FIG. 3, high energy implantation is used, i.e. carried out at about 1 mega-electron-volt (MeV).

By way of illustrative example, with such an implantation energy and by implanting monoatomic hydrogen into a silicon wafer in a suitable dose (of the order of 10¹⁷ hydrogen atoms, for example), it is possible to obtain an implantation depth of about 15 μm.

Equipment for accomplishing such an implantation energy currently exists. In Japan, for example, the Japan Atomic Energy Research Institute (JAERI) has developed and used a hydrogen implanter in the 1 MeV energy range with the specific property of retaining a charge state of −1 for hydrogen ions (H- ions). For helium, International patent application WO-A-00/61841, for example, uses an implantation energy of 3.8 MeV.

The subsequent steps of the method, shown in FIGS. 4 and 5, include detaching the rear portion 7 of the wafer 1.

In the present case, the rear portion 7 is sufficiently thick to be in the form of a monoblock layer, i.e., forming a whole.

It is then detached from the front portion 6 by applying heat treatment and/or by applying external mechanical stresses.

More precisely, detachment can be accomplished either solely under the action of supplying a suitable thermal budget, by heating the wafer 1 to a temperature sufficient to cause detachment (arrows S, see FIG. 6) of the two portions 6 and 7 of the wafer, or solely by applying external mechanical stresses with no heat treatment.

In a variation, detachment can also be accomplished by means of an external mechanical stress applied during or after the heat treatment step.

Applying a mechanical stress may include applying a bending and/or tensile stress, or applying shear to the two portions 6 and 7, or introducing a blade or a jet of a fluid (liquid or gas), which may be continuous or may vary with time, at the interface of the layers to be detached.

Ultrasound can also be applied, if desired.

The source of the external mechanical stresses can also be electrical energy (application of an electrostatic or an electromagnetic field).

Stresses derived from heat energy may originate from applying an electromagnetic field, an electron beam, thermoelectric heating, a cryogenic fluid, a super-cooled fluid, etc.

The front portion 6 obtained constitutes a thin layer with a thickness of about 35 μm. This thin layer supports components and/or circuits 3.

The rear face 4″ of the thin layer can be polished in some cases (see FIG. 6) or it can undergo a variety of appropriate surface treatments so that it becomes completely planar. However, flatness is not obligatory since it is after all only the rear face.

The thin layer 6 obtained has sufficient thickness to be self-supported, and can then be cut and transferred chip by chip, to a plasticized support card, for example. Chip cutting can also take place prior to thinning.

If the thickness removed, i.e. the thickness of the rear portion 7, is insufficient, the steps of implantation and detachment illustrated in FIGS. 3, 4 and 5 are repeated on the rear face 4″ of the front portion 6 (or thin layer 6) until it has the desired thickness, i.e. a thickness close to 30 μm.

It should be noted that very high energy implantation, i.e. beyond 1 MeV (for example 5 MeV) could increase the ion implantation depth P and remove a still greater thickness of material.

By means of the method of the invention, it is possible to thin the wafer 1 without deteriorating the electronic components 3 when these components are present on the front face 2 prior to implanting.

Further, by knowing the thickness of the original wafer 1 and by appropriate selection of the atomic species implantation parameters, it becomes possible to reduce the thickness of the wafer 1 in one or more passes by eliminating a pre-determined thickness to produce, in a relatively accurate manner, the desired final thickness for the layer 6.

The method of the invention enables implantation units to be used in an optimum manner. In general, we commence with thinning by high energy implantation to remove a rear portion 7 of substantial thickness, then it is refined by implanting at a lower energy to remove a smaller thickness.

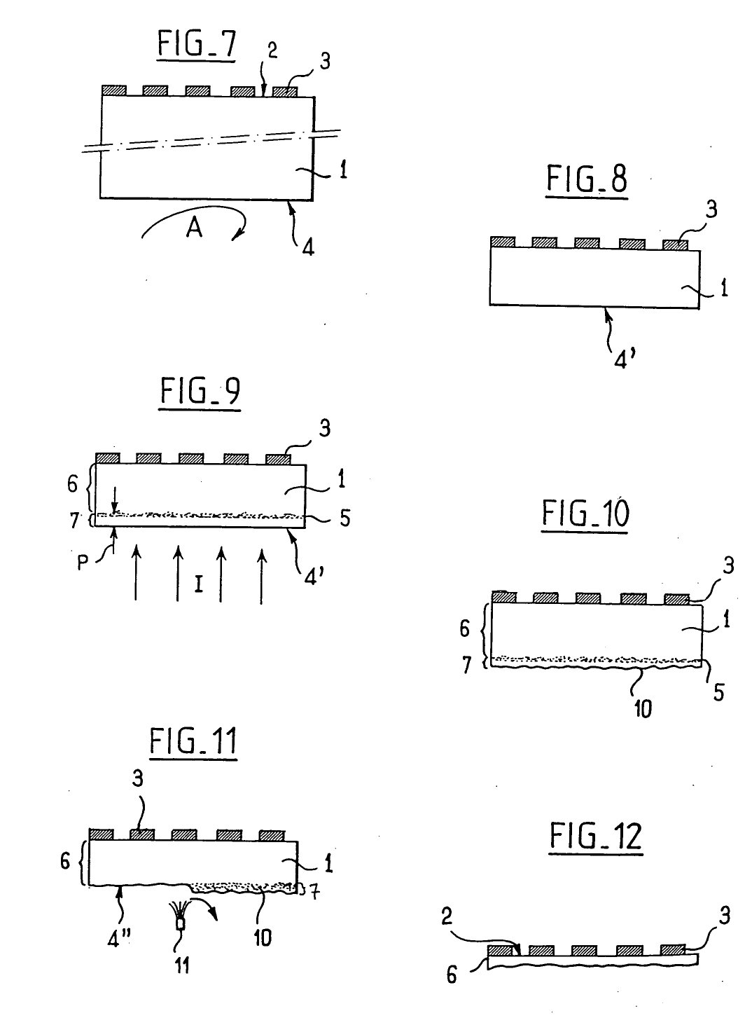

A second implementation of the method of the invention is illustrated in FIGS. 7 to 12.

FIG. 9 illustrates the step of implanting atomic species carried out on the rear face 4′ of the thinned wafer (or even directly on the rear face 4 of the wafer 1 that has not already been thinned).

In this case, implantation is carried out using implanters that are currently routinely used in microelectronics. The implantation energy is low, i.e. close to a few hundred kilo-electron-volts (keV).

For implantation, reference should be made to the above description of the first implementation.

As an example, when implanting monoatomic hydrogen into silicon at an implantation energy of 210 keV with an implantation dose in the range 2×10¹⁶ to 10¹⁷ monoatomic hydrogen atoms per square centimeter (cm²), a zone of weakness 5 can be produced at an implantation depth P of about 1.5 μm to 2 μm.

FIGS. 10 and 11 illustrate the step of detaching rear portion 7.

In this range of small implantation thicknesses, the rear portion 7 does not exfoliate, or only partially. It does not have a homogeneous appearance. Blisters 10 are formed and the rear portion 7 has the appearance of a plurality of pieces of material (crumbs).

A shown in FIG. 11, the rear portion 7 is then detached, for example using a scrubber 11 or by spraying a jet of a fluid (for example a jet of liquid under pressure or a jet of gas, such as compressed air). The scrubber 11 used is, for example, a scrubber such as those routinely used in microelectronics in association with chemical-mechanical polishing steps (CMP). The term “scrubbing” also encompasses any other equivalent technique that is known to the skilled person that can remove particles and other pieces of material, such as polishing or using a scraper.

The steps of implantation and detachment of the rear portion 7, illustrated in FIGS. 9, 10 and 11, are repeated on the rear face 4″ of the front portion 6 until the self-supported thin layer shown in FIG. 12 is obtained.

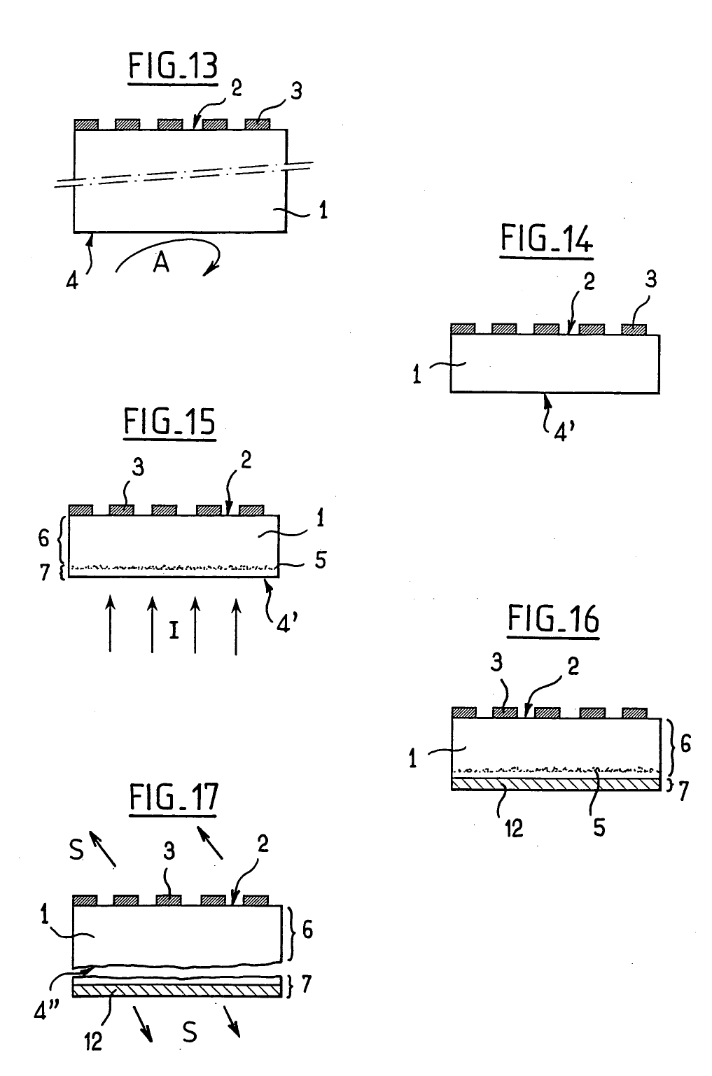

FIGS. 13 to 17 illustrate a third implementation of the method of the invention.

The step of low energy atomic species implantation illustrated in FIG. 15 is identical to that just described in relation to FIG. 9.

After the implantation operation, a stiffener 12 is applied to the rear face 4′ of the thinned wafer (or the rear face 4 of the unthinned wafer).

The term “application” means both application by deposition, such as spraying or chemical vapor deposition (CVD), and physical application including placing a rigid plate or a flexible film on the front face 2. Such techniques are known to the skilled person.

The rigid plate may be a glass plate or a monocrystalline or polycrystalline silicon plate.

The flexible film may be a film formed from a plastics material, or polytetrafluoroethylene, trade mark “Teflon”, or an adhesive strip.

The stiffener can also be a layer of wax.

In the case of a deposit, it is advantageously a layer of silicon oxide (SiO₂), for example.

When the stiffener 12 is a rigid plate or a flexible film, it can be bonded by molecular bonding or by eutectic bonding. In this case, the surface quality of the rear surface of the substrate must be high, or it must be polished.

The stiffener 12 can also be bonded with an adhesive.

It is then removed (see FIG. 17) by applying mechanical stresses (arrows S) or, when it is bonded, by a heat treatment to eliminate the adhesive bonding it to the wafer 1, or by a chemical treatment, known as lift-off (dissolving the adhesive by the action of a suitable solvent).

The operations illustrated in FIGS. 15, 16 and 17 can be repeated a plurality of times on the rear face 4″ of the front portion 6 (or thin layer 6) until it has the desired thickness (step illustrated in FIGS. 6 or 12).

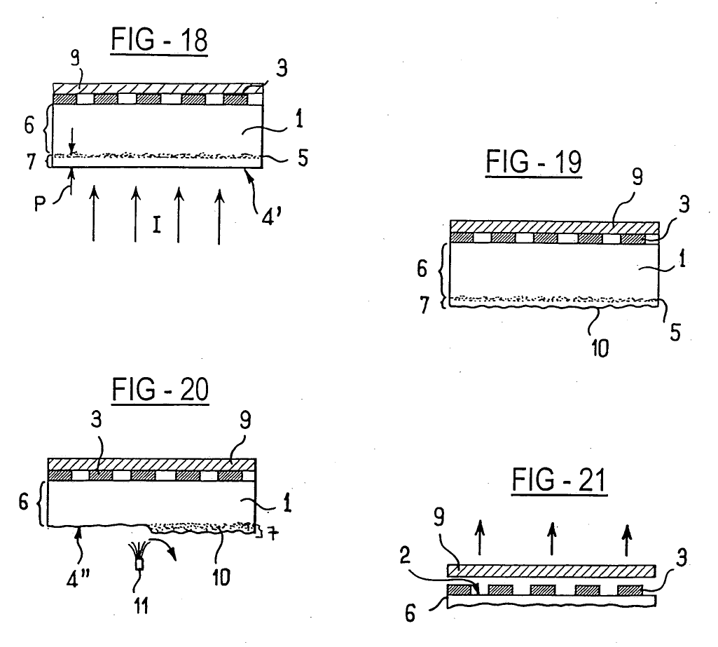

Finally, FIGS. 18 to 21 illustrate a variation of the method of the invention, in which a stiffener 9 is applied to the front face 2 of the wafer 1, either prior to the atomic species implantation step (see FIG. 18) or immediately after that step (see FIG. 19), so that the stiffener 9 is present when the rear portion 7 is detached.

The description pertaining to the stiffener 12 is also applicable to stiffener 9, and thus the stiffener will not be described further.

The stiffener 9 has the sole function of temporarily facilitating manipulation of the front portion 6 obtained, in particular when the thinning operations carried out on the rear face are repeated a plurality of times.

Once the desired thickness of the self-supported layer has been obtained, that stiffener 9 can be removed using a suitable treatment, during the last step of the method (see FIG. 21). It can optionally be removed after cutting and embedding the layer 6.

The thinning method that has been described (regardless of the selected implementation) has the advantage of being carried out on standard wafers which are routinely used in micro-electronics, on which electronic components and/or circuits are disposed using the usual equipment. Thus, there is absolutely no need to modify those prior steps of producing the wafer before carrying out the method of the invention.

More generally; this method is applicable to any substrate carrying or intended to carry electronic components on its front face.

### EXAMPLES

Seven particular examples of the method of the invention will now be given.

### Example 1

A monocrystalline silicon wafer 1, 200 mm in diameter and 725 μm thick, the front face 2 of which supported electronic components and/or circuits 3, underwent a first mechanical and/or chemical thinning step. A 50 μm thick thinned wafer was thus obtained.

A step of implanting H⁺ions with an energy of 1 MeV was then carried out on the rear face 4′ of the thinned wafer using an implantation dose of 1.8×10¹⁷ H⁺/cm². Implantation was carried out at ambient temperature. The mean implantation depth P was 15 μm.

Heat stress was then applied to the wafer by heating to 400° C., which allowed exfoliation of the rear portion 7 to a thickness of about 15 μm.

The thin layer 6 obtained was 35 μm thick.

### Example 2

The procedure was identical to that described for Example 1, except that the heat treatment was carried out at 350° C. and the rear portion 7, in the form of a continuous monoblock film, was removed by tearing using an adhesive strip (temporary stiffener).

The thin layer 6 obtained was 35 μm thick.

### Example 3

The prior thinning and implantation steps were identical to those described for Example 2, except that before the first mechanical and/or chemical thinning step, a stiffener 9 was deposited on the front face 2 of the wafer. This stiffener 9 was a silicon wafer bonded by a 5 μm thick oxide layer, planarized prior to bonding, bonding being accomplished by wafer bonding.

The thin layer 6 obtained was 35 μm thick.

### Example 4

This example repeated Example 1, with the exception that after mechanical and/or chemical thinning, the wafer 1 was 35 μm thick, implantation was plasma implantation, the implantation energy was 200 keV, the mean implantation depth P was 2 μm, the implantation dose was 1×10¹⁷ H⁺/cm² and the heat treatment was carried out at 400° C.

Scrubbing was then carried out to remove the rear portion 7.

The front portion 6 obtained was 33 μm thick.

The cycle of operations was repeated once more to obtain a thin layer 6 with a final thickness of 31 μm.

### Example 5

The prior thinning and implantation steps were identical to those described for Example 1 with the exception that after mechanical and/or chemical thinning, the wafer 1 was 35 μm thick, the implantation energy was 200 keV, the mean implantation depth P was 2 μm and the implantation dose was 1×10¹⁷ H⁺/cm².

Prior to implantation, a temporary stiffener 9 constituted by a glass plate was bonded to the front face 2. Bonding was accomplished using a UV reversible adhesive.

After detaching the rear portion 7, the front portion 6 obtained was 33 μm thick.

The cycle of operations was repeated twice more to obtain a thin layer 6 with a final thickness of 29 μm after removing the stiffener 9, if necessary adding a new stiffener 9 to the front face 2 between each cycle.

### Example 6

The prior thinning and implantation steps were identical to those described for Example 1, with the exception that after mechanical and/or chemical thinning, the wafer 1 was 40 μm thick, the implantation energy was 750 keV, the mean implantation depth P was 10 μm and the implantation dose was 1.3×10¹⁷ H⁺/cm².

Further, prior to the implantation step, a stiffener 9 constituted by a glass plate was bonded to the front face 2. Bonding was accomplished using a UV reversible adhesive.

After implantation, a stiffener 12 constituted by a glass plate was bonded to the rear face. Bonding was accomplished using a UV reversible adhesive.

The rear portion 7 was then mechanically separated by introducing a blade or a jet of air or compressed water between the two glass plates at the zone of weakness 5.

The self-supported layer 6 obtained was 30 μm thick.

### Example 7

A monocrystalline silicon wafer 1, 200 mm in diameter and a 725 μm thick, the front face 2 of which supported electronic components and/or circuits 3, underwent a first mechanical and/or chemical thinning step. A thinned wafer with a thickness of 40 μm was thus obtained.

A step of implanting H⁺ ions with an energy of 750 keV was then carried out on the rear face 4′ using an implantation dose of 1.3×10¹⁷ H⁺/cm². Implantation was carried out at ambient temperature. The mean implantation depth P was 10 μm.

Prior to the first mechanical and/or chemical thinning step, a stiffener 9 was deposited on the front face 2 of the wafer. The stiffener 9 was a silicon wafer bonded via a 5 μm thick oxide layer, planarized prior to bonding, bonding being carried out by wafer bonding. The stiffener remained in place until the end of the method and would be removed when the desired thickness of layer 6 had been obtained.

Heat stress was then applied to the wafer by heating to 400° C. then scrubbing, which allowed exfoliation of the rear portion 7.

The front portion 6 obtained was 30 μm thick and constituted a self-supported layer.

In the examples described above, the wafer 1 was formed from silicon.

However, it would also be possible to produce it from a material selected from germanium, an alloy of silicon and germanium (SiGe), silicon carbide, gallium arsenide, indium phosphide, gallium nitride or aluminum nitride. The wafer 1 could also be a SOI (silicon on insulator) type substrate.

What is claimed is:

1. A method of thinning a wafer made of semiconductor material, the wafer having a first face supporting or for supporting at least one electronic component or circuit and an opposing second face which comprises:
implanting atomic species through the second face and into the wafer to obtain a zone of weakness at a predetermined depth therein, the zone defining a first portion of the wafer extending from the zone to the first face and a remaining portion constituted by the remaining portion of the wafer;
removing the remaining portion from the first portion along the zone of weakness to thin the wafer; and
repeating the implanting and removing steps until the first portion has a reduced thickness that corresponds to a desired thickness for constituting a self-supported thin layer for the electronic component or circuit.

2. The method of claim 1, which further comprises thinning the wafer by a mechanical or chemical thinning method prior to the implanting of the atomic species.

3. The method of claim 1, which further comprises providing at least one electronic component or circuit on the first face of the wafer prior to the implanting of the atomic species.

4. The method of claim 1, wherein the remaining portion of the wafer is removed by applying a heat treatment or an external mechanical stress.

5. The method of claim 1, wherein the remaining portion of the wafer is removed by blowing a jet of fluid adjacent the zone of weakness.

6. The method of claim 1, wherein the remaining portion of the wafer is removed by scrubbing.

7. The method of claim 1, which further comprises applying a stiffener to the second face of the wafer prior to removing the remaining portion by the application of a heat treatment or external mechanical stress.

8. The method of claim 7, which further comprises applying the stiffener by deposition.

9. The method of claim 8, wherein the stiffener comprises a layer of silicon oxide.

10. The method of claim 7, wherein the stiffener comprises a rigid plate.

11. The method of claim 10, wherein the rigid plate comprises a monocrystalline or polycrystalline silicon material or a glass.

12. The method of claim 7, wherein the stiffener comprises a flexible film.

13. The method of claim 7, wherein the stiffener comprises an adhesive film.

14. The method of claim 7, wherein the stiffener comprises a layer of wax.

15. The method of claim 1, which further comprises applying a stiffener to the first face of the wafer and removing the stiffener after having obtained the self-supported thin layer prior to the removal of the remaining portion.

16. The method of claim 1, wherein the wafer comprises silicon.

17. The method of claim 1, wherein the wafer comprises a silicon on insulator wafer.

18. The method of claim 1, wherein the wafer comprises germanium, an alloy of silicon and germanium, silicon carbide, gallium arsenide, indium phosphide, gallium nitride or aluminum nitride.

19. A method of thinning a wafer made of semiconductor material, the wafer having first and second opposing faces, which comprises:
providing at least one electronic component or circuit on the first face of the wafer;
implanting atomic species through the second face and into the wafer to obtain a zone of weakness at a predetermined depth therein, the zone defining a first portion of the wafer extending from the zone to the first face and a remaining portion constituted by the remaining portion of the wafer;
removing the remaining portion from the first portion along the zone of weakness to thin the wafer; and
if necessary, repeating the implanting and removing steps until the first portion has a reduced thickness that corresponds to a desired thickness for constituting a self-supported thin layer for the electronic component or circuit.
